(19) United States
(12) Patent Application Publication
(10) Pub. No.: US 2024/0014628 A1
(43) Pub. Date: Jan. 11, 2024

(54) METHOD FOR PRODUCING A PACKAGE, AND OPTOELECTRONIC DEVICE

(71) Applicant: ams-OSRAM International GmbH, Regensburg (DE)

(72) Inventors: Zeljko Pajkic, Regensburg (DE); Markus Boss, Regensburg (DE); Michael Müller, Eching (DE)

(73) Assignee: ams-OSRAM International GmbH, Regensburg (DE)

(21) Appl. No.: 18/245,185

(22) PCT Filed: Aug. 30, 2021
(86) PCT No.: PCT/EP2021/073914

§ 371 Date: Mar. 14, 2023

(30) Foreign Application Priority Data
Sep. 15, 2020 (DE) 10 2020 124 008.2

(51) Int. Cl. H01S 5/02315; H01S 5/02257; H01S 5/068

(52) U.S. Cl. CPC H01S 5/02315; H01S 5/02257; H01S 5/06825; H01S 5/183

(57) ABSTRACT

In a method of manufacturing a package, in particular an injection molded circuit carrier, MID, at least one injection molded cover plate forming a cavity is provided having a cover area and a perimeter defining the cover area; wherein the cover area includes an opening. Two conductive traces having a first portion on a top edge of the surround, a second portion on a side surface of the surround, and a third portion on the cover area are formed, and then an optical element is formed in the opening of the cover area. Finally, a loop-shaped interlock circuit is applied to the optical element in an edge portion between the opening and the cover area, wherein one end of the loop-shaped interlock circuit is connected to each of the first and second conductive paths.

### CROSS-REFERENCE TO RELATED APPLICATIONS

The present application is a national stage entry from International Application No. PCT/EP2021/073917, filed on Aug. 30, 2021, published as International Publication No. WO 2022/058149 A1 on Mar. 24, 2022, and claims priority to DE application 10 2020 124 008.2 filed Sep. 15, 2020, the disclosures of all of which are hereby incorporated by reference in their entireties.

### FIELD

The present invention relates to a method of manufacturing a package comprising an optoelectronic device, in particular an injection molded circuit carrier, MID. The invention further relates to an optoelectronic device.

### BACKGROUND

In some applications involving lasers, they are packaged, with a lens or other optical element provided to focus the beam. In addition to beam shaping, the optical element may also perform some protective or safeguarding function, ensuring that laser radiation does not inadvertently enter a person's eye.

For this purpose, a so-called interlock circuit is used, i.e. a conductor loop is arranged between the optical element and the package or the optical element and the laser. If the optical element or the package is damaged, the conductor loop is interrupted and the optoelectronic element is switched off.

In the manufacture of such packages, the conductor loop and MLA (optically active structure) are located on opposite surfaces for technical reasons, which limits the design options. As a result, it is currently necessary to glue over the conductor loop. In the past, however, problems arose due to thermomechanical stress between the components to be bonded (cap <->conductive adhesive+non-conductive adhesive <->MLA) in addition to excessive scrap. The punctual conductive bonding and thus interrupted structural bonding do not allow sufficient bonding of the components to be bonded. This can lead to thermally induced damage and thus failure of the entire package. Thus, there is a need to disclose a method of manufacturing a package, in particular an injection molded circuit carrier, MID, in which a thermal stress is reduced during an operation.

### SUMMARY OF THE INVENTION

The inventors have recognized that with suitable combinations of different manufacturing techniques, thermally induced displacement of the optical element relative to the cap is reduced. Separation of the lens from the cap becomes less likely. This can be aided by the use of mechanical anchors. One aspect of this is to use the manufacturing process to provide the conductor loop and MLA (optically active structure) on the same side of the optical element. This eliminates the need to bond over the conductor loop, reducing shear or other thermally induced forces on the joint.

In one aspect, a method of manufacturing a package, in particular an injection molded circuit carrier, MID, is proposed. Thereby, at least one injection molded cover plate forming a cavity is provided having a cover area and a perimeter defining the cover area, wherein the cover area comprises an opening. The cover plate thus forms an injection molded part. A first conductive trace and a second conductive trace are then formed on the cover plate, each of the first and second conductive traces comprising a first portion on a top edge of the surround, a second portion on a side surface of the surround, and a third portion on the cover area. Next, an optical element is formed in the opening of the cover area such that the optical element is intimately connected to the cover area. A loop-shaped interlock circuit is then applied to the optical element in an edge portion between the opening and the cover area, wherein one end of the loop-shaped interlock circuit is connected to each of the first and second conductive paths. Thus, the loop-shaped interlock circuit is located on the optical element near the edge of the cover area. In the case of a corresponding optical element which terminates planarly with the edge of the cover area, the loop is thus also arranged planarly on the optical element and the cover area or the conductor track.

In the process, an optoelectronic component can also be introduced into the cavity. This can be, for example, an optoelectronic component for ToF applications (time of flight) with a VCSEL emitter and integrated IC driver. The optoelectronic component can also include an emitter (LED, laser), a detector (e.g. photodiode), a sensor and passive components such as capacitors or ESD and ICs. Combinations of such elements are also possible.

In one aspect, the aperture has a step in the cover area, wherein the optical element extends onto the step and the loop-shaped interlock circuit is disposed over the step. The step is also referred to as a perimeter. As a result, an adhesive can be applied to the step to allow an optical element to fit snugly in the opening. In addition, the step in the opening provides an additional support surface for the optical element, e.g. in a subsequent molding process, thus reducing the intimate connection and thus the risk of detachment. The opening can be square or rectangular in shape, and is optionally arranged off-center in the cover plate.

In a further aspect, the opening comprises a particularly semicircular bulge on one side, particularly between the first and second conductive tracks. The bulge can accommodate excess adhesive or excess material of the optical element. This allows manufacturing tolerances to be compensated.

Various methods may be used to create the first and second conductive paths. In one aspect, a laser-activatable metal compound is provided as a plastic additive that is present at the locations or regions of the cover plate that will later form the conductive traces. In one aspect, the cover plate may be immediately fully molded with a plastic doped with the laser-activatable metal compound. A suitable material is a solder-stable thermoplastic based on PPA, LCD or PPS. Then, areas of the first, second and third sections of each trace are activated by laser to create metallic nuclei at these locations. The nuclei are used in a further deposition process, in particular in an electrodeposition process, to form a metallic layer or a metallic and gold-containing layer sequence.

In another aspect for creating a first and a second conductive path, the cover area and at least a portion of the side surface of the perimeter and the top edge of the perimeter are metallized. An etch resist is then applied to the cover area, and the perimeter, and laser-induced exposure of the etch resist is used to pattern the first, second, and third portions in the metallized areas of the perimeter. The unexposed areas are then removed and the metallization is removed by etching, for example.

In another aspect, the injection-molded cover plate is produced by two-component injection molding in two shot molding stages. One plastic forms the base body, while another can be metallized and forms the conductor track layout. There are two common methods for this, known as the PCK and SKW processes. Depending on the process, the metallizable plastic must be activated.

Among other things, a layer with copper is used as the material of the conductor path. Copper is also suitable as a nucleus for depositing a layer sequence as described above. In one aspect, the layer sequence is a Cu-Ni-Au layer with gold as the top layer. The thickness of the trace can vary in the individual sections, and is for example between 200 μm and 500 μm.

Another aspect relates to the step of forming an optical element. In this step, a material of the optical element is laser-induced or electrolytically removed, in particular in the area of the conductive path or on the cover area, so that the material of the optical element remains only in the area of the opening.

In one aspect, to create the optical element, the cover plate is placed in a bottom mold, particularly made of a UV transparent material. The bottom mold may be planar in one example, or structured (e.g., with protrusions or bulges) in another example, such that a lenticular optical element may be formed. In this case, the placement is such that the patterning is over the opening of the cover plate. A transparent optical element material is then placed in the cavity and opening in the cover plate. This can be done by dispensing, jetting or any other suitable means. In particular, the amount of material is selected to be substantially equal to a volume of the opening relative to the top and bottom edges of the cover area, or the volume including a volume of the bottom plate. More generally formulated, the quantity is chosen such that the upper side of the later optical element is flush with the upper side of the cover area.

Optionally, a cover mold made of a UV transparent material in particular can then be applied to fill the cavity of the cover plate. The transparent material of the optical element is cured and then the cover mold and bottom mold are removed. The cover mold and bottom mold can be made of PDMS, for example.

Alternatively, in another aspect, the step of forming an optical element may comprise the steps of:
Applying an adhesive to or on the edge area of the opening, especially on a step in the opening;
Providing and aligning the optical element in the opening;
Bonding of the optical element to the cover area;
Filling of a gap between the cover area edge and the optical element caused by size tolerances and dimensions with a material, in particular a resin or adhesive.

In this manufacturing variant, the optical element is manufactured separately and then glued into the opening and onto the step in particular. The material quantity of the adhesive is selected accordingly. Excess adhesive can flow into the bulge. It is also possible to fill any gap caused by manufacturing tolerances with material in a process following the gluing step, so that the gap is planarized.

Another aspect relates to the step of applying a loop-shaped interlock circuit. In this step, a conductive material, for example a silver-based conductive polymer, is applied to the optical element in the edge region, with the ends in electrical connection to the conductive tracks, thus electrically coupling them to each other. A dispensing process, a jet process, a laser-induced transfer process or another suitable application process can be used for this purpose. Suitable materials include conductive silver, a conductive resin or a conductive polymer doped with a metal such as silver.

In one aspect, the end portions of the loop-shaped interlock circuit may be disposed on the first and second conductive paths, thereby electrically connecting them. To this end, a width of the interlock circuit may be less than a width of the first or second conductive path. A thickness of the interlock circuit may be in the range of 100 μm to 200 μm. Generally, however, the thickness and also the width of the interlock circuit are smaller than the corresponding dimension of the conductor tracks.

The method may also be provided for a plurality of cavity forming cover plates. Thus, in one aspect, the step of providing at least one injection molded cavity forming cover plate comprises providing a plurality of interconnected cavity forming cover plates arranged in rows and columns. The further steps are then performed for each cover plate of the plurality of cover plates, preferably in parallel. In addition, after completion of the optical element and the interlock circuit, the plurality of interconnected cover plates arranged in rows and columns each forming a cavity can be separated.

As mentioned above, the first and second traces may have a thickness in the range of 200 μm to 500 μm. The interlock circuit may include a smaller thickness, particularly in the range of 100 μm to 200 μm.

Another aspect relates to an optoelectronic device. This comprises a cover plate made according to the aspects and methods proposed herein. Further, an optoelectronic and light emitting device is disposed in the cavity. This has a light emitting surface facing the optical element. Thus, the loop-shaped interlock circuit is arranged between the optical element and the light-emitting surface of the optoelectronic component. It is further proposed to electrically couple the optoelectronic component to the interlock circuit in such a way that the component is switched off when the interlock circuit is interrupted.

In one embodiment, the optoelectronic device is a VCSEL or a laser.

### BRIEF DESCRIPTION OF THE DRAWING

In the following, the invention is explained in detail with reference to the drawings by means of some embodiments. Thus show:

FIG. 1 a top view of a known package;

FIG. 2 Side views illustrating various shear or tensile forces that can cause unintentional tearing;

FIG. 3 a perspective view of a first embodiment to illustrate some aspects of the proposed principle;

FIGS. 4A to 4G show different steps of a first method with some aspects of the proposed principle;

FIG. 5 a side view of the above embodiment of a package with a component;

FIG. 6 is a perspective view of a second embodiment to illustrate some aspects of the proposed principle;

FIGS. 7A to 7E different steps of a second method with some aspects of the proposed principle.

The following embodiment examples concern various aspects and combinations thereof according to the proposed principle. In this context, the embodiment examples are not generally shown to scale. Likewise, various elements may be shown enlarged or reduced in size to emphasize individual aspects. However, it will be understood by those skilled in the art that the aspects illustrated herein may be combined with each other in the various embodiments and process steps without detriment to the inventive concept. Some aspects show a regular structure or shape. It should be noted here that slight differences and deviations from the ideal shape occur in practice, but without this being contrary to the inventive idea.

### DETAILED DESCRIPTION

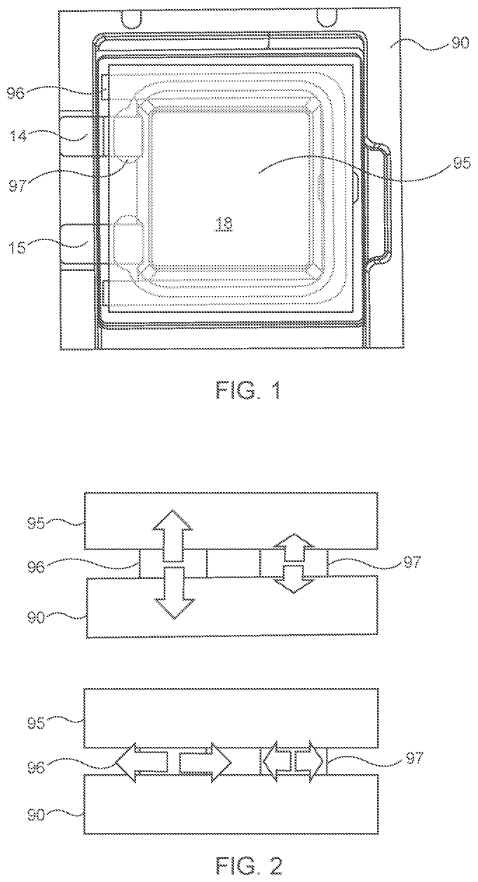

FIG. 1 shows an embodiment of an MID cap with an inserted optical element, which is intended for use with VCSEL lasers, for example. The cap comprises a housing 90, which is also referred to as a cover plate. A recess is made in the housing 90, in which an opening 18 is located. An optical element is disposed over the opening in the recess of the housing 90 and secured thereto via an adhesive. Two adhesives 96 and 97 are provided substantially for this purpose. Firstly, a non-conductive adhesive 96 is applied here directly to the edge of the recess adjacent the opening 18 in a U-shape. A conductive adhesive 97 is arranged on this adhesive, at least in sections, which thus also forms a conductor loop and is electrically coupled with its two end regions to the conductor tracks 14 and 15, respectively. Various design aspects are possible with regard to the precise arrangement and configuration of the conductive or non-conductive adhesive.

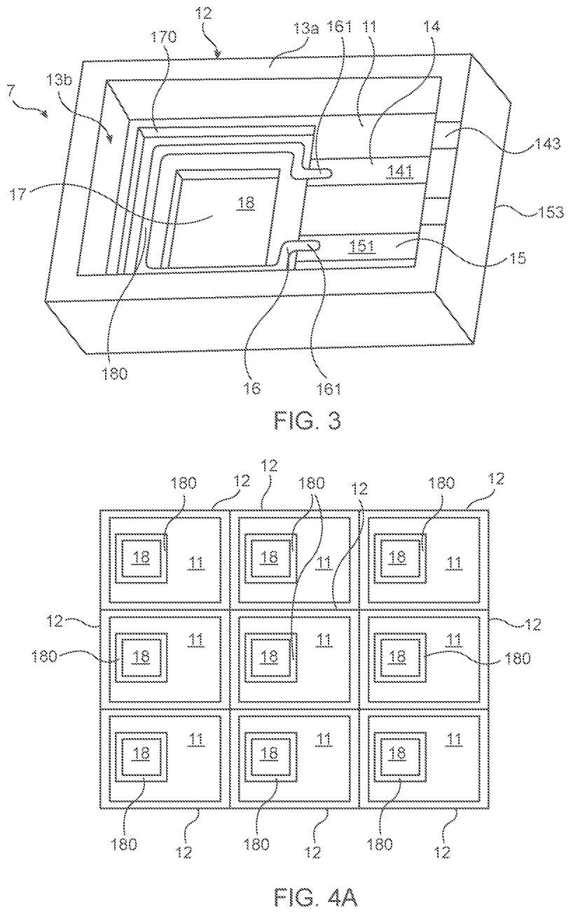

FIGS. 1 and 2, however, illustrate the underlying problem. The optical element 95, for example epoxy or a polymer, is attached to the MID cap on the one hand with the non-conductive adhesive 96 and on the other hand with the conductive adhesive 97. In the two embodiments shown in FIG. 2, the two adhesives are arranged side by side. In this process, the problem now arises that a thermo-mechanical stress occurs between the components to be bonded. This results from a different coefficient of thermal expansion between the non-conductive adhesive 96 and the conductive adhesive 97, as shown by the two arrows of different lengths. In this regard, a thermo-mechanical stress or pull can occur both in the direction of the cap and the optical element and substantially parallel to these two elements. Accordingly, for example, the conductive adhesive 97 may be torn off and damaged even though the optical element remains firmly secured in the cavity via the non-conductive adhesive. The component is thus considered damaged and replaced, even though the optical element continues to be sealed. On the other hand, the thermo-mechanical stress itself may also cause damage to the optical element, reducing yield and lifetime.

The inventors have recognized that a change in the manufacturing process, as described in the following figures, results in a reduction in mechanical stress, thereby allowing a reduction in thermally-induced displacement of the optical element relative to the cap. This makes separation of the optical element from the cap less likely. In addition, this effect can be favored by the use of mechanical anchors, mechanical stress both during manufacturing and during a subsequent operation is thus reduced, leading on the one hand to an increase in component reliability and on the other hand to an improved production yield.

For this purpose, it is proposed, among other things, to arrange the electrical conductor loop as well as the optical element on the same side as an optically active structure. This means that there is no need to glue over the conductor loop or the interlock circuit, so that this component is omitted from an overall thermo-mechanical consideration.

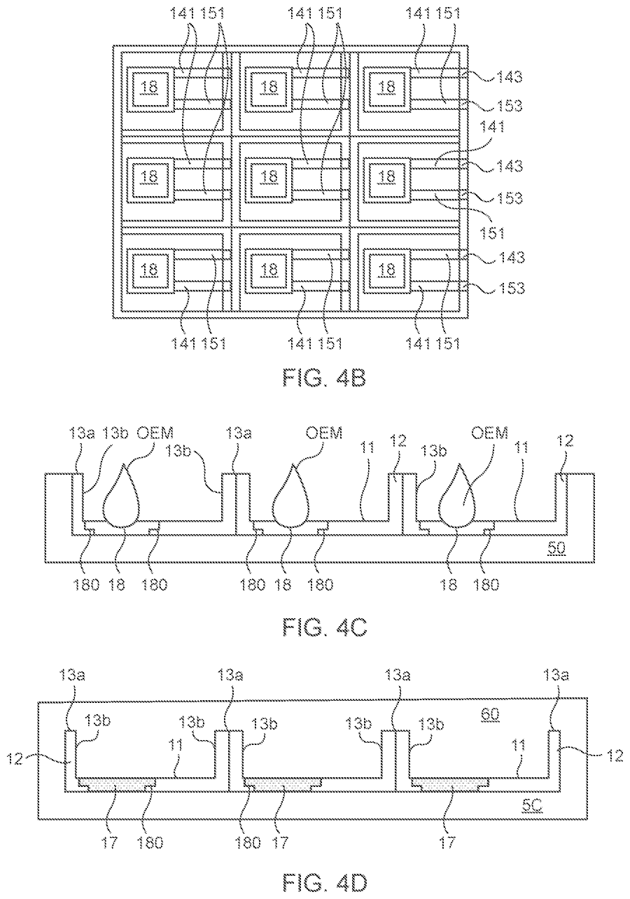

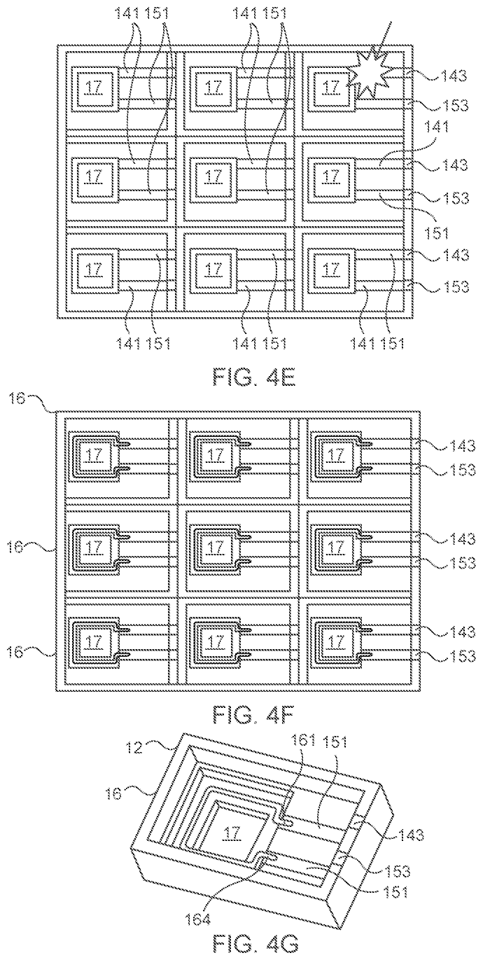

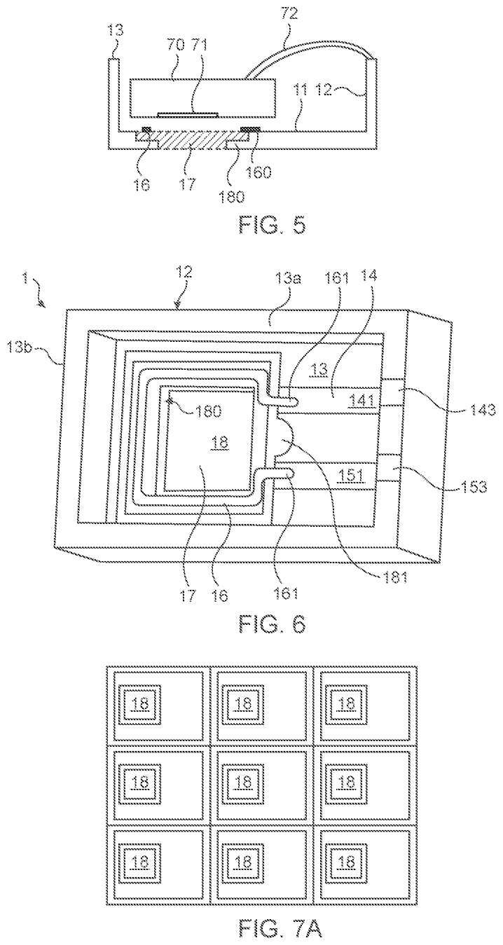

FIG. 3 shows a perspective view of a first embodiment with an innovative optical element according to the proposed principle. The package is designed as a rectangular cover plate 1 with a cavity and has a cover area 11 surrounded by a perimeter 12. The thickness of the perimeter can be some 10 μm to 100 μm. The length of the entire object is substantially 3 mm to 5 mm, and the width is in the range of 1 mm to 3 mm. The perimeter comprises a cover area 13a and an inner side surface 13b. An opening 18 is formed in the cover area and extends through the cover area. In addition, another recess is disposed around the opening 18 in the cover area, referred to as the edge region or perimeter 180. In FIGS. 4C and D as well as FIG. 5, the edge region 180 is shown in cross-section.

In the edge area 180 and thus above the opening, an optical transparent element 17 is arranged, the manufacturing method of which will be explained in detail below. In addition, a circumferential conductor loop 16, which represents an interlock circuit, is located in the edge region 180 on the optical element 17. The conductor loop 16 is electrically connected with its end regions 161 to a first conductor track 14 and a second conductor track 15, respectively. The first and second conductive traces thus electrically connect the interlock circuit 16. Damage to the interlock circuit 16 results in either an increase in resistance or other parameter change, such as a drop in current or an increase in voltage across the conductive traces 14 and 15. First and second conductive traces are applied as a metallic interconnect to the surface of the cover area 11, the side walls 13b, and the top edge of the perimeter 13a. Specifically, each conductive trace includes a first conductive trace section 141 and 151, respectively, applied to the cover area. A second section 143 and 144 (not shown here) runs along the inner sidewall 13b to the top edge 13a, where it forms the third section 143 and 153, respectively. This metallic interconnect allows the conductor loop and interlock circuit 16, respectively, to be routed outwardly or connected to an opto-electronic device to secure operation of the opto-electronic device.

FIGS. 4A to 4G now show various process steps to illustrate a process for producing such a package. It should be mentioned at this point that the proposed package can be manufactured in both single and matrix form. Accordingly, the process steps presented here according to FIGS. 4A to 4G are to be regarded as examples, and can be scaled in any way. Moreover, the shape forming the cover plate 1 may be not only rectangular, but also square, oval or any other shape. The cover plate 1 is made of a plastic material into which dyes for light absorption, for example carbon and the like, may additionally be incorporated. Using a suitable preform, the cover plate is produced as a matrix, in FIG. 4A as a 3×3 matrix, by means of injection molding. The opening 18 can be formed immediately during injection molding. However, it is also possible to punch out, cut out or otherwise create the opening 18 in a later step. Adjacent to the opening 18 is the perimeter area 180, which is also slightly recessed relative to the rest of the cover area 11. Each perimeter 12 is adjacent on at least two sides to a perimeter of an adjacent cover panel, as shown.

FIG. 4B shows a next step of the proposed principle. In this step, an MID process is used to transfer the traces 14 and 15 to each cover plate. Such a process is, for example, laser induced and is carried out by first structuring the conductive tracks to be generated later by means of a laser. For this purpose, the cover plate is formed from a plastic which has a non-conductive metallic compound. The laser-induced activation causes a physical or chemical reaction in the plastic, which releases metallic nucleation cells from the metallic compound, e.g. of copper for the later conductor tracks. By using laser-induced activation, it is also possible to “write” the conductive traces not only on the first and third sections, but also along the side walls as well as the top edge. After laser-induced activation, the conductive tracks 14 or 15 are now generated in the respective sections by subjecting the matrix shown here to one or more electroplating steps. As a result, various layers are formed on the nucleation cells of copper.

For example, such a sequence of layers can consist of copper, nickel and a top gold layer.

Other ways of creating traces, such as those shown in FIG. 4B, are also possible.

For example, instead of the laser-induced process proposed here, a two-component injection molding process can also be provided for the workpiece. In this process, a first metallizable plastic is prepared which reproduces the conductor track layout. However, this metallizable plastic is not itself electrically conductive, but is activated by various measures in a later step, as already shown above. A metal layer or metal layer sequence can be applied to the then metallized surface. The second plastic is non-metallizable, whereby the mold is finally filled by the second non-metallizable plastic and thus predetermined.

Another method of production is by means of an embossing process in which the existing conductive tracks are applied to and bonded to the plastic mold as a surface-modified metal foil by means of a carrier tool using pressure and heat. Although this process is particularly simple, one difficulty is that it is difficult to create side surfaces with it as in the embodiment presented. This is why this process is particularly suitable for simple planar designs. Equally possible would be processes such as film back injection or direct conductor drawing, in which metals such as copper are melted and then sprayed or otherwise raised onto the substrate materials using compressed air or inert gas. Depending on the size and design of the package, different steps and processes can thus be used to create the first and second conductor tracks.

FIG. 4C shows the next process step in a side view. The three covers 1 in total are connected to each other via the respective perimeter 12. Each cover comprises an opening 18 as well as a rim 180 surrounding the opening, which is slightly recessed with respect to an upper side of the cover area 11. The covers are inserted into a bottom body 50, which is positively sealed thereto. In this embodiment, the bottom body is unstructured, that is, in particular, the bottom body is flat and planar over the respective openings 18 of the individual covers. However, in other embodiments, this particular region of the bottom body may be additionally structured, for example, slightly curved bulging, spherical or otherwise shaped. In this way, a lens shape can be realized via the shape of the bottom plate above the openings 18.

In a subsequent step after placing the covers in the bottom mold, a liquid transparent material OEM is now introduced into the opening and onto the edge area of the opening. The amount of material is chosen so that the volume is substantially equal to the volume of the opening 18 as well as the edge area 180. In this manner, the material so introduced forms a substantially planar surface with the cover area of the cover area. The transparent material OEM may be, for example, a transparent polymer, acrylate or other transparent plastic. In this context, it is convenient to select a transparent material whose coefficient of thermal expansion is substantially the same as the coefficient of expansion of the surrounding plastic of the cover. In this way, a thermomechanical load on the component during an operation is reduced.

FIG. 4D shows the next step, in which a cover mold is now applied to the cover plate. The cover mold extends into the cavity of the cover plate and closes in a planar manner with the surface of the cover area 11 and thus with the material applied. Lid mold 60 and base mold 50 are transparent to UV light and are formed, for example, on a PDMS basis. This makes it possible to cure the material introduced into the opening 18 by means of UV light in a subsequent step and thus form the optical element 17.

In addition, the cover and bottom molds are configured such that the optical material 17 does not adhere or stick to these molds even after curing, so that both molds can be removed after curing without damaging the optical element. As a result, the optical element 17 is thus introduced into the opening as a transparent liquid or viscous material and cured so that it is intimately bonded to the cover area. In some embodiments, not shown here, the perimeter may additionally have small hooks or a rough surface that improves adhesion of the material OEM and the optical element with the cover area 11.

After the lid mold and optionally also the base mold have been cured and lifted off, a so-called laser deflashing is carried out in this embodiment. Excess transparent material, particularly in the area of the conductor tracks, is removed by laser so that subsequent electrical contact with the interlock circuit is ensured. In addition, unevenness in the material can also be evened out in this way. At the same time, laser deflashing can be used to activate the corresponding area of the respective conductor tracks and thus prepare them for a subsequent metal-to-metal connection.

In FIG. 4F, the interlock circuit 16 is now applied using a dispensing or jet process. For this purpose, a conductor loop is formed, which extends along the respective edge area 180, around each opening 18. The interlock circuit 16 is thus located within the edge area 180 above the material of the optical element 17. In the event of damage or separation of the optical element 17, the interlock circuit is also damaged. A first end portion of the circuit is disposed on the end portion of the conductor section 143. Accordingly, a second end region of the interlock circuit is electrically connected to an end region of the first portion 153 of the second conductor section 15.

As shown in this embodiment, a width of the interlock circuit 16 is significantly smaller than the corresponding width of the conductive tracks 14 or 15. The thinner embodiment, for example in the range of less than 10 μm to 100 μm, ensures that even slight damage to the optical element will cause the interlock circuit 16 to unravel and thus break the electrical connection. FIG. 4G shows an embodiment after mechanical separation of the matrix shown above into its individual packages. The separation can be done by sawing, cutting or other mechanical processes. Each package produced in this manner thus comprises an optical element produced by the method set forth above. The conductor loop or interlock circuit 16 on the optical element serves to provide safety for a user or viewer. To the extent that electrical contact no longer exists, it can be assumed that there is damage to the optical element that could result in an eye safety violation. As a result, the optical element not shown is turned off. As disclosed in these embodiments, the interlock circuit is formed as a simple conductor loop. In other embodiments, the interlock circuit may have a different configuration or shape.

For example, it is quite possible to design it in a meandering shape, i.e. with several loops. If possible, the interlock circuit can also be drawn completely over the opening, in particular if this does not impair the light guidance or only insignificantly. In this way, direct damage to the optical element 17 in the opening can also be detected without damage in the edge region.

FIG. 5 shows a cross-sectional view of the package manufactured according to the proposed principle with an electronic component 70 arranged therein, which is designed, for example, in the form of a VCSEL laser. The optoelectronic component 70 is arranged with its emitter surface 71 above the optical element 17. A distance of a few micrometers to a few 100 μm may be provided between the surface of the optical element 17 and the emitter surface 71. This aspect may, for example, reduce a thermal load on the optical element.

The conductor loop 16 is arranged above the perimeter 180 and is connected in the area 160 to the conductor tracks not shown here. The distance between the optoelectronic component 70 and the optical element 17 with the interlock circuit 16 mounted thereon also ensures that the interlock circuit 16 can be safely torn off if the optical element is damaged, thereby severing the connection. The optical element is also electrically coupled to the conductive paths 14 and 15 via bonding wires or other electrically conductive connections 72.

In one operation of this arrangement, a laser light is now generated in the laser 70 and emitted to the outside via the optical element 17. At the same time, a voltage is applied to conductive paths 14 and 15 and the resistance or other electrical parameter is evaluated. Conductive paths 14 and 15 can also be used directly as a current supply for the optical element.

In the event of damage to the optical element 17, the interlock circuit 16 now ruptures at one point and the electrically conductive connection between the conductor tracks 14 and 15 is interrupted. This interruption manifests itself, for example, in an abrupt breaking of a current through the conductive tracks or an increase in the resistance or voltage across the interlock circuit. In the first case, if power is supplied to the device 70 via the conductive traces 14 and 15, the disconnection of the interlock circuit directly shuts down the device. Alternatively, the resistance, voltage, or current flow across traces 14 and 15 can be evaluated and, if there is a change from a set point, the device can be electronically turned off.

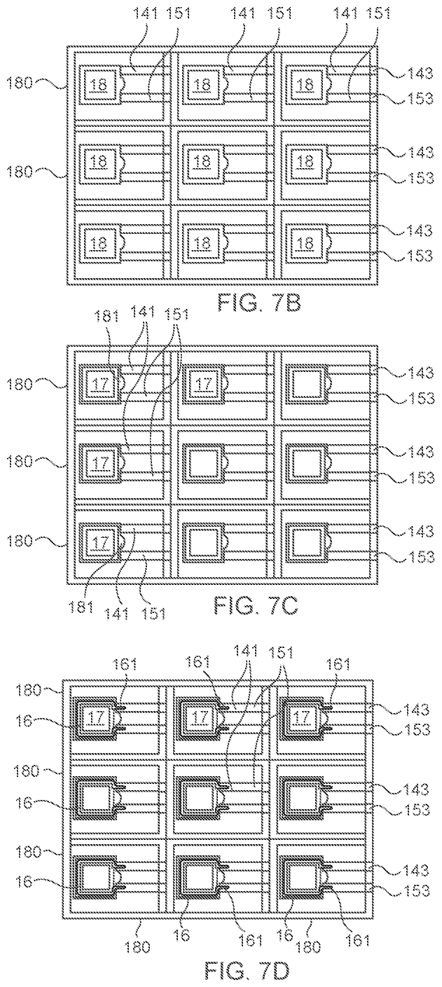

FIG. 6 shows a second embodiment example of a package in an alternative manufacturing method, wherein the interlock circuit 16 runs on the surface of the optical element 17. As already shown in the embodiment example of FIG. 3, the package comprises a cover plate 1 with a cover area 11 and a perimeter 12 surrounding the cover area 11. Conductive tracks 14 and 15 with respective sections 141, 151 to 143, 153 are applied to the cover area 11, a side surface 13b of the perimeter and the upper edge 13a of the perimeter. As in the previous example, the cover area 11 has an opening 18 which is of square configuration and is surrounded by an edge region 180 which is also of square configuration.

In contrast to the previous example, however, a bulge 181 is still provided. An optical element 17, which has already been manufactured in advance, is now inserted into the opening 18 and firmly bonded in the edge area 180 by means of adhesive. In one aspect, the bulge 181 now serves to receive excess adhesive. In addition, as shown here, the optical element 17 is made with slightly smaller dimensions than the dimension of the edge region 180. This results in a small gap between the edge of the optical element 17 and the edge of the perimeter 180 forming the cover area. Depending on the application, this gap is filled with an adhesive or with another plastic or a combination of both, leaving the excess plastic or adhesive in the bulge 181. Thus, the bulge 181 serves as a buffer for excess adhesive or other plastic.

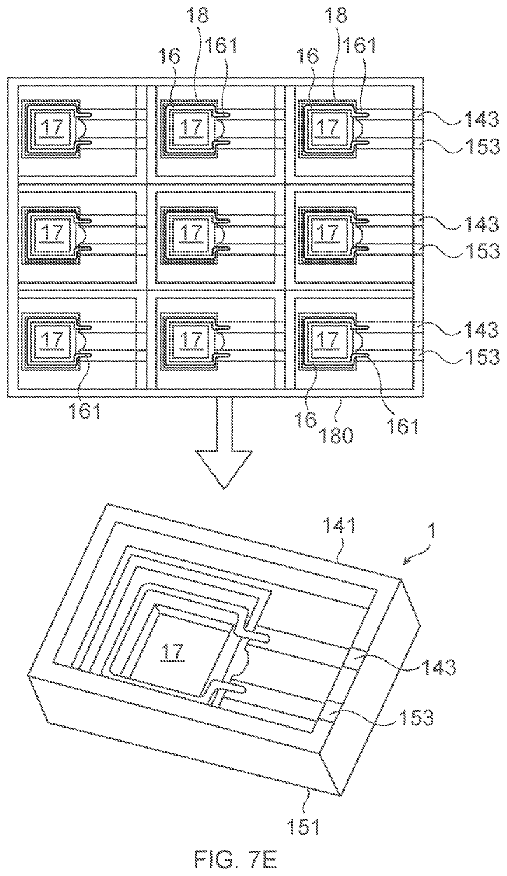

FIGS. 7A to 7E show the various process steps for manufacturing a package according to FIG. 6.

In a first step according to FIG. 7A, a matrix of cover plates 1 with opening 18 provided therein is produced by an injection molding process similar to the previous embodiment example of FIG. 4A. In subsequent steps, the conductive paths 14 and 15 are formed by the various MID processes. This step is shown in FIG. 7B and is substantially the same as the step shown in FIG. 4B.

Then, as shown in FIG. 7C, a thin adhesive, for example an epoxy or similar material, is applied to the perimeter 180 surrounding the opening 18. A prefabricated lens 17 is then aligned in the opening and bonded to the rim 180 and into the opening by means of the adhesive.

As shown in FIG. 7C, a small gap remains between the edge of the optical element 17 and the frame 180. Depending on the design, this may already be at least partially filled with the adhesive. Otherwise, a so-called lens potting is carried out by means of a further step, in which a plastic material is filled into the gap by jet or a dispensing process. Furthermore, the plastic material also flows into the bulge 181, which thereby serves as a reservoir and receptacle for excess material during the lens-potting step. It should be noted at this point that the plastic material thus introduced can be flexible and elastic, so that it also acts as a buffer against thermo-mechanical stress. In this way, the optical element 18 remains in position even under greater thermal stress and the stress on the element 17 is reduced.

After curing, optional laser deflashing may be performed to remove material from the end regions of the traces from the lens potting or bonding step. Next, in step 7D, the interlock circuit can be applied to the optical element 17, such as a lens, by jetting or dispensing or other suitable processes. The end portions 161 of the interlock circuit 16 are electrically conductively connected to the end portions of the first sections 141 and 151, respectively. The material of the lens, as well as the material in the plastic, is thereby selected in its height such that this substantially closes with the cover area. As a result, the interlock circuit runs essentially planar in the area of the perimeter up to the end area of the respective conductor track section 141 or 151. Accordingly, a risk of the conductor loop 16 breaking off is already reduced during the manufacturing process.

The resulting structure in FIG. 7E is separated, as in the previous example, by cutting, sawing or similar processes. The resulting structure in FIG. 7E is separated, as in the previous example, by cutting, sawing or similar processes, and thus separated into individual cover plates 1. The cover plates can now be provided with an electronic component, and this is electrically coupled to the conductor tracks 14 and 15, for example in the region of the third sections 143 and 153.

The methods and embodiments proposed here can be combined in any way without this being detrimental to the idea of the invention. By designing the conductor loop or the interlock circuit on the surface of the optical element, a thermally induced stress is reduced. The conductor loop and the interlock circuit as well as the optically active structure are now located on the same side of the optical element. This also eliminates the need to bond over the conductor loop.

1. A method of manufacturing a package for an optoelectronic component, in particular an injection-molded circuit carrier, MID, comprising:
providing at least one injection molded cavity forming cover plate having a cover area and a perimeter defining the cover area; wherein the cover area comprises an opening (18);
generating a first conductive trace and a second conductive trace, each conductive trace of the first and second conductive traces comprising a first portion on a top edge of the perimeter, a second portion on a side surface of the perimeter, and a third portion on the cover area;
forming an optical element in the opening of the cover area such that it is intimately connected to the cover area; and
applying a loop-shaped interlock circuit to the optical element in an edge region between the opening and the cover area, wherein one end of the loop-shaped interlock circuit is connected to each of the first and second conductor tracks.

2. The method according to claim 1, wherein the aperture includes a step in the cover area, the optical element extending onto the step, and the looped interlock circuit disposed over the step.

3. The method according to claim 1, wherein the opening is square or rectangular in shape, optionally arranged decentrally in the cover plate.

4. The method according to claim 1, in which the opening has a bulge, in particular a semicircular bulge, on at least one side, in particular between first and second conductor tracks.

5. The method according to claim 1, wherein the step of generating a first conductive trace and a second conductive trace comprises:
applying of a laser-activatable metal compound as a plastic additive
laser induced activation in the area of the first, second and third section of each trace;
depositing, in particular electrodeposition of a metallic layer or a metallic and gold-containing layer sequence;

6. The method according to claim 1, wherein the step of generating a first conductive trace and a second conductive trace comprises:
metallizing the cover area and at least part of the side surface of the perimeter as well as the top edge of the perimeter;
applying an etch resist to the cover area, and the perimeter;
laser-induced exposing the etch resist to pattern the first, second and third sections in the metallized areas of the perimeter; and
removing of the remaining metallization.

7. The method according to claim 1, wherein the step of forming an optical element comprises the step of laser-induced or electrolytic removal of material of the optical element, in particular in the region of the conductive path or on the cover area.

8. The method according to claim 1, wherein the step of forming an optical element comprises:
placing the cover plate in a bottom mold, in particular made of a UV transparent material;
introducing, in particular dispensing, a transparent material into the opening, the quantity being selected in particular such that it corresponds to a volume of the opening in relation to the upper and lower edges of the cover area;
optional applying of a cover mold, in particular made of a UV transparent material, to fill the cavity of the cover plate;
curing of the transparent material; and
removing the bottom mold and the optional lid mold.

9. The method according to claim 1, wherein the step of forming an optical element comprises:
applying an adhesive to or on the edge area of the opening, especially on a step in the opening;
providing and aligning the optical element in the opening;
bonding of the optical element to the cover area; and
filling of a gap between the cover area edge and the optical element caused by size tolerances and dimensions with a material, in particular a resin or adhesive.

10. The method according to claim 1, wherein the step of applying a looped interlock circuit comprises at least one of the following steps:
dispensing a conductive material, especially a silver-based conductive polymer;
jetting a conductive material, particularly a silver-based conductive polymer; and
laser-induced transfer of a conductive material, especially a silver-based conductive polymer.

11. The method according to claim 10, wherein end portions of the looped interlock circuit are disposed on the conductive traces such that the looped interlock circuit connects the first and second conductive traces.

12. The method according to claim 1, wherein a width of the interlock circuit is smaller than a width of the first or second conductive path.

13. The method according to claim 1, wherein the step of providing at least one injection molded cavity forming cover plate comprises providing a plurality of interconnected cavity forming cover plates each arranged in rows and columns, and the method further comprises:
separating the plurality of interconnected cover plates arranged in rows and columns, each forming a cavity.

14. The method according to claim 1, wherein the first and second conductive traces have a thickness in the range of 200 μm to 500 μm, and the interlock circuit has a smaller thickness, in particular in the range of 100 μm to 200 μm.

15. An optoelectronic device comprising:
a cover plate according to claim 1;
an optoelectronic device disposed in the cavity with a light emitting surface opposite the optical element, the optoelectronic device being electrically coupled to the interlock circuit.

16. The optoelectronic device according to claim 15, wherein the optoelectronic device is a VCSEL.
